(19) United States
(12) Patent Application Publication
(10) Pub. No.: US 2004/0157161 A1
(43) Pub. Date: Aug. 12, 2004

(54) Method and apparatus for the hardening of photopolymer plates

(76) Inventor: Glen L. Wright, Arcadia (AU)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 10/475,439

(22) PCT Filed: Apr. 19, 2002
(86) PCT No.: PCT/AU02/00497

(30) Foreign Application Priority Data
Apr. 20, 2001 (AU) PR4516

(51) Int. Cl. G03F 7/16

(52) U.S. Cl. 430/300; 430/302; 430/270.1; 101/453; 101/457

(57) ABSTRACT

A machine (10) hardens polymer steel backed foil stamping plates. The machine (10) includes a housing (11) providing a surface (12) upon which the plate to be hardened rests. Magnets (16) are provided to urge the steel backed polymer plate into contact with the surface (12). The polymer plate is heated to a temperature of 60 to 70° C. for 5 to 10 minutes. The polymer plates are employed in stamping and embossing of foil to another material such as paper or plastics.

### TECHNICAL FIELD

The present invention relates to methods and apparatus for hardening photopolymer plates employed in stamping and embossing.

### BACKGROUND OF THE INVENTION

Described in Australian Patent Application 17618/95 is a magnetic holding device used to secure in position steel backed polymer plates. Force and heat are applied to the plates for the purposes of transferring thin metal foil or leaf to paper, card, plastics material or similar media.

When photopolymer was introduced to the market approximately 10 years ago, it was promoted as being capable for use to foil stamp. To efficiently foil stamp the photopolymer needed to have heat conductively similar to the more traditionally materials such as magnesium, brass, zinc, copper and steel. It also needed to cope with the combination of heat and pressure.

The use of photopolymer had a number of advantages compared to previous materials, such as water as opposed to acid for washing, a smooth finish as opposed to a grained finish, lower cost of materials and lower cost of plate making equipment.

The magnetic holding device of the above-mentioned Australian patent application encouraged the use of photopolymer as it improved the delivery of heat to the photopolymer. It also overcame the need for adhesive tape to secure the plate in position and therefore problems in respect of heat conductivity and cleaning. Still further, the use of the above-mentioned magnetic holding device facilitated easy removal and easy positioning of the plate.

Typically, the photopolymer was hardened by firstly exposing the photopolymer to black light under vacuum with negative film for three to five minutes, washing the photopolymer for three to five minutes, drying the photopolymer and then again exposing the photopolymer to black light for 4 to 6 minutes. For foil stamping the photopolymer needs to be hardened, this was done by heating to approximately 150° C. for approximately 15 minutes. This was called “post baking”. This “post baking” was generally performed within the foil stamping device as no specific equipment was available to hardening photopolymer plates.

The use of photopolymer in foil stamping, despite its advantages, has been hindered by its short life cycle. Generally the plates had a life of approximately 500 to 1000 runs. Such a life expectancy is generally unacceptable in the field of graphic arts, such as foil stamping.

Described in International Application PCT-AU00-00482 is a modification of the above-described magnetic holding device, that is the device described in Australian Patent Application 17618/95.

Previously known machines to harden a steel backed photopolymer plate were generally complex and therefore costly to manufacture. They are also known to be unreliable. A further disadvantage includes the space they occupy.

### OBJECT OF THE INVENTION

It is the object of the present invention to overcome or substantially ameliorate the above disadvantage.

### SUMMARY OF THE INVENTION

There is disclosed herein a method for hardening a photopolymer plate, said method including the steps of:

securing the photopolymer plate to a heating plate; and

activating the heating plate to heat the photopolymer plate to a temperature of:

(i) 60 to 70° C. for 5 to 10 minutes;

(ii) 88 to 98° C. for 5 to 10 minutes;

(iii) 116 to 126° C. for 20 to 45 minutes; and

(iv) 135 to 140° C. for 5 to 10 minutes.

Preferably the temperature for the step (i) is about 65° C., (ii) 93° C., (iii) 121° C., (iv) about 140° C.

Preferably the photopolymer plate has a steel backing, and said heater plate has magnets to urge said photopolymer plate into contact therewith.

Preferably said heater plate is heated by the application of radiant heat.

There is further disclosed herein a machine to harden a steel backed photopolymer plate, said machine having:

a heating plate upon which the photopolymer plate is supported, the heating plate including magnets to urge the photopolymer plate into contact with the heating plate;

a heater operatively associated with the heating plate to raise the temperature thereof; and

control means operatively associated with said heater to determine the temperature of said heating plate and the periods during which the photopolymer plate is heated at desired temperatures.

Preferably the above machine includes means to selectively cool the heating plate for removal of the photopolymer plate.

### BRIEF DESCRIPTION OF THE DRAWINGS

Preferred forms of the present invention will now be described by way of examples with reference to the accompanying drawings wherein:

FIG. 1 is a schematic perspective view of a machine to harden a photopolymer steel backed foil stamping plate, such as that described in Australian Patent Application 17618/95 and International Application PCT/AU00/00428;

FIG. 2 is a schematic side elevation of the device of FIG. 1;

FIG. 3 is a schematic top plan view of the device of FIG. 1;

FIG. 4 is a schematic section end elevation of the device of FIG. 1; and

FIG. 5 is a schematic circuit diagram employed in the device of FIG. 1.

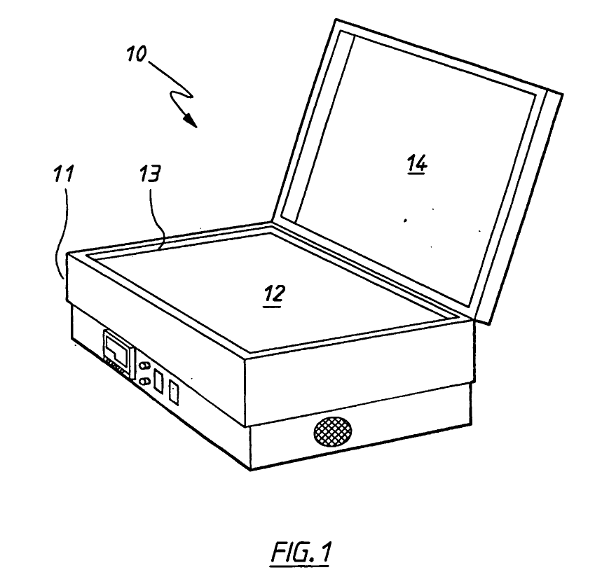

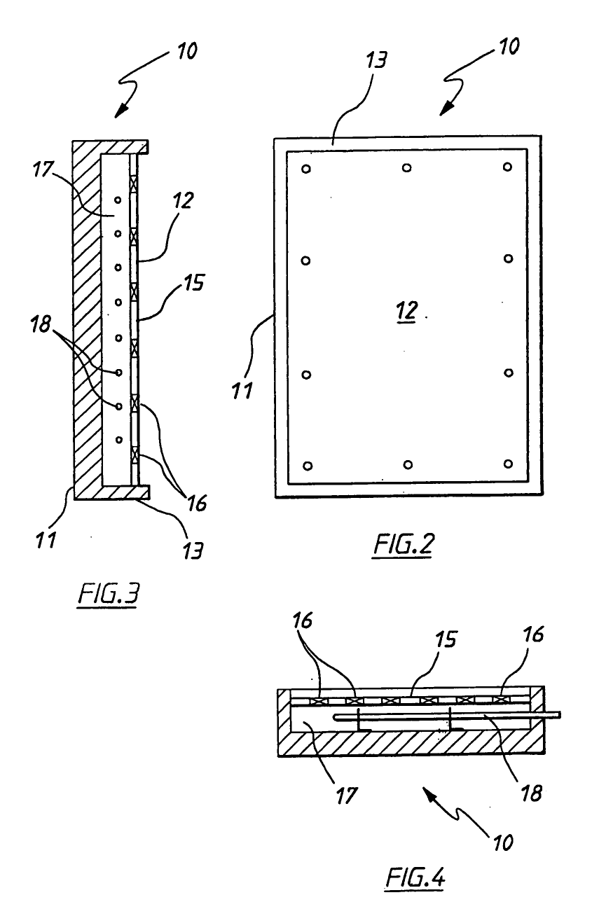

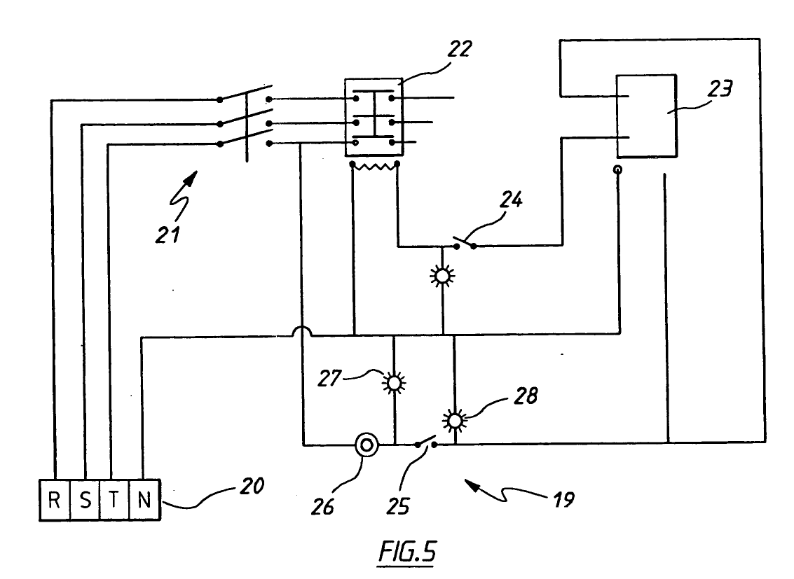

### DETAILED DESCRIPTION OF THE PREFERRED EMBODIMENT

In the accompanying drawings there is schematically depicted a machine 10 to harden a photopolymer steel backed foil stamping plate. The machine 10 includes a hollow housing 11 providing a surface 12 upon which the plate to be hardened rests. Surrounding the plate 12 is a circumferential flange 13 upon which a lid 14 rests so as to provide a cavity within which the plate to be hardened is located. The surface 12 is provided by a generally planar sheet member 15 within which there is embedded a plurality of magnets 16. The magnets 16 are provided to urge the steel backed polymer plate into contact with the surface 12.

The housing 11 provides a cavity 17 within which there is located a heating element 18. The heating element 18 is associated with a control circuit 19 to thereby control the heat of the plate 15 and the temperature to which the photopolymer plate is subjected. The control circuit 19 is operable to control the heat cycle to which the photopolymer plate is subjected.

The circuit 19 includes a connection 20 to connect four lines to a supply voltage, such as 220, 240 or 380 volts. Associated with the three lines is a relay 21, which lines are then connected to a controller 22. The controller 22 is directly connected to the heating element 18 so as to deliver electric power thereto. More particularly, the controller 22 is a digital processor that is pre-programmed and receives information from the thermostat 23. The controller 22 controls delivery of electricity to the element 18 and therefore the heat cycle that the plate is subjected. The controller 22 cooperates with a thermostat 23 by way of a switch 24. The thermostat 23 by the switch 27 provides a signal indicating the temperature of the plate being heated.

A main power switch 25 provides for the connection of the thermostat 23 while a fuse 26 is provided in line with the switch 25. Lamps 27 and 28 indicate when the device 10 is connected to a main supply and when the device 10 is operative.

The heating element 18 is controlled so that the polymer plate is heated to a temperature of:

60 to 70° C. for 5 to 10 minutes, then 88 to 98° C. for 5 to 10 minutes, then 116 to 126° C. for 20 to 45 minutes, and then 135 to 144° C. for 5 to 10 minutes. Preferably the plate is heated to about 65° C. for 5 to 10 minutes, 93° C. for 5 to 10 minutes, 121° C. for 20 to 45 minutes and then 140° C. for 5 to 10 minutes.

The claims defining the invention are as follows:

1. A method for hardening a photopolymer plate, said method including the steps of:
securing the photopolymer plate to a heating plate; and
activating the heating plate to heat the photopolymer plate to a temperature of:
(i) 60 to 70° C. for 5 to 10 minutes;
(ii) 88 to 98° C. for 5 to 10 minutes;
(iii) 116 to 126° C. for 20 to 45 minutes; and
(iv) 135 to 140° C. for 5 to 10 minutes.

2. The method of claim 1, wherein the temperature for the step (i) is about 65° C., (ii) 93° C., (iii) 121° C., (iv) about 140° C.

3. The method of claim 1 or 2, wherein the photopolymer plate has a steel backing, and said heater plate has magnets to urge said photopolymer plate into contact therewith.

4. The method of claim 1, 2 or 3, wherein said heater plate is heated by the application of radiant heat.

5. A machine to harden a steel backed photopolymer plate, said machine having:
a heating plate upon which the photopolymer plate is supported, the heating plate including magnets to urge the photopolymer plate into contact with the heating plate;
a heater operatively associated with the heating plate to raise the temperature thereof; and
control means operatively associated with said heater to determine the temperature of said heating plate and the periods during which the photopolymer plate is heated at desired temperatures.

6. The machine of claim 5, further including means to selectively cool the heating plate for removal of the photopolymer plate.

7. A method for hardening a polymer plate substantially as hereinbefore described with reference to the accompanying drawings.

8. A machine to harden a steel backed polymer plate substantially as hereinbefore described with reference to the accompanying drawings.
